(19) United States
(12) Patent Application Publication
(10) Pub. No.: US 2019/0144987 A1
(43) Pub. Date: May 16, 2019

(54) MASK ASSEMBLY AND MANUFACTURING METHOD THEREOF

(71) Applicants: BOE Technology Group Co., Ltd., Beijing (CN); Chengdu BOE Optoelectronics Technology Co., Ltd., Chengdu (CN)

(72) Inventors: Dengjun Guo, Beijing (CN); Yongmao Wang, Beijing (CN); Wenchang Zhang, Beijing (CN)

(21) Appl. No.: 16/027,457

(22) Filed: Jul. 5, 2018

(30) Foreign Application Priority Data
Nov. 10, 2017 (CN) 201711102683.1

(51) Int. Cl. C23C 14/04; H01L 51/56; H01L 51/00; C23C 14/24

(52) U.S. Cl. CPC C23C 14/042; C23C 14/24; H01L 51/0011; H01L 51/56

(57) ABSTRACT

A mask assembly and manufacturing method thereof are provided. The mask assembly includes: a frame, a first mask and a second mask stacked on the frame. The second mask has at least one evaporation region with each being provided with a plurality of evaporation holes having the same shape. The first mask includes a plurality of cross-arranged sub-masks defining at least one open region. The at least one open region is in one-to-one correspondence to the at least one evaporation region, and includes at least one irregular open region. An orthographic projection of each irregular open region on the second mask is located in a corresponding evaporation region. With the mask assembly, the phenomenon of poor color-mixing during evaporation due to the uneven surface of the second mask can be avoided when the irregular display panel is manufactured, and the display reliability of the manufactured display panel can be improved.

### CROSS-REFERENCE TO RELATED APPLICATION

This application claims priority to Chinese Patent Application No. 201711102683.1, filed with the State Intellectual Property Office on Nov. 10, 2017 and titled “MASK ASSEMBLY AND MANUFACTURING METHOD THEREOF”, the entire contents of which are incorporated herein by reference.

### TECHNICAL FIELD

The present disclosure relates to a mask assembly and the manufacturing method thereof.

### BACKGROUND

An Organic Light-Emitting Diode (OLED) display is a display with an autonomous light-emitting function. OLED displays are widely used in the display industry due to the advantages of thin thickness, light weight, active light emission, fast response, wide viewing angle, rich colors, high brightness, low power consumption, as well as high and low temperature resistance. In the manufacturing process of the OLED display, an evaporation machine can be used in coordination with a mask assembly, and the OLED material can be evaporated on a substrate by a way of evaporation, so as to form an organic light emitting pattern on the substrate to obtain an array substrate.

Currently, a mask assembly generally includes a metal frame, a metal shielding sheet mask, and a fine metal mask (FMM). The metal shielding sheet mask herein includes a first strip metal shielding sheet array and a second strip metal shielding sheet array that are perpendicular to each other, and two ends of each strip metal shielding sheet in the first strip metal shielding sheet array and the second strip metal shielding sheet array are respectively welded on the metal frame. The first strip metal shielding sheet array and the second strip metal shielding sheet array are formed with a plurality of open regions, and the FMM includes a plurality of evaporation regions for forming a plurality of array substrates in a one-to-one correspondence manner. Each of the evaporation regions is provided with a plurality of evaporation holes for forming pixels, and orthographic projections of the evaporation regions on the metal shielding sheet mask are located in the open regions.

### SUMMARY

There are provided, in embodiments of the present disclosure, a mask assembly and the manufacturing method thereof.

In an aspect, there is provided a mask assembly including a frame, and a first mask and a second mask stacked on the frame; where the second mask has at least one evaporation region, and each evaporation region is provided with a plurality of evaporation holes having the same shape; the first mask includes a plurality of cross-arranged sub-masks, the plurality of cross-arranged sub-masks define at least one open region, the at least one open region is in one-to-one correspondence to the at least one evaporation region, the at least one open region includes at least one irregular open region, and an orthographic projection of each irregular open region on the second mask is located in a corresponding evaporation region.

Optionally, the second mask further has a buffer region surrounding each evaporation region; the plurality of sub-masks include at least one irregular sub-mask, each irregular sub-mask includes a strip structure and a protruding structure extending outward from an edge of the strip structure, an orthographic projection of the strip structure on the second mask is located in the buffer region, and an orthographic projection of the protruding structure on the second mask at least partially coincides with the evaporation region.

Optionally, the at least one open region is an irregular open region, the plurality of sub-masks include a plurality of first sub-masks arranged in a array along a first direction and a plurality of second sub-masks arranged in an array along a second direction, and the first direction is perpendicular to the second direction; the plurality of first sub-masks are the irregular sub-masks, and the plurality of second sub-masks are strip sub-masks.

Optionally, the at least one open region is an irregular open region, the plurality of sub-masks include a plurality of first sub-masks arranged in an array along a first direction and a plurality of second sub-masks arranged in an array along a second direction, and the first direction is perpendicular to the second direction; the plurality of first sub-masks are strip sub-masks, and the plurality of second sub-masks are the irregular sub-masks.

Optionally, the at least one open region is an irregular open region, the plurality of sub-masks include a plurality of first sub-masks arranged in an array along a first direction and a plurality of second sub-masks arranged in an array along a second direction, and the first direction is perpendicular to the second direction; the plurality of first sub-masks and the plurality of second sub-masks are all the irregular sub-masks.

Optionally, the protruding structure is arranged at a designated position on each irregular sub-mask, and the designated position is an edge close to a corresponding irregular open region at an intersection with the other sub-masks.

Optionally, the evaporation region has a rectangular shape, the buffer region has a rectangular ring shape, and the irregular open region has a rounded rectangle shape.

Optionally, each protruding structure is a trapezoid with curved edges, the trapezoid with curved edges includes two base sides parallel to each other and two curved sides connected to the two base sides respectively, orthogonal projections of the two curved sides on the second mask are located in the evaporation region, and orthogonal projections of the two base sides on the second mask are located in the buffer region.

Optionally, each protruding structure is a triangle with curved sides, the triangle with curved sides includes at least one curved side, an orthographic projection of a target curved side in the at least one curved side on the second mask is located in the evaporation region, and except for the target curved side, orthographic projections of the other sides of the triangle with curved sides on the second mask are located in the buffer region.

Optionally, the first mask is a metal shielding sheet mask, and the second mask is a fine metal mask.

Optionally, the frame is a metal frame, the first mask is welded on the metal frame, and the second mask is welded on the first mask.

Optionally, the protruding structure is arranged at a designated position on each irregular sub-mask, and the designated position is an edge close to a corresponding irregular open region at an intersection with the other sub-masks.

In another aspect, there is provided a method for manufacturing a mask assembly, including steps of: providing a frame; arranging a first mask on the frame, where the first mask includes a plurality of cross-arranged sub-masks, the plurality of cross-arranged sub-masks define at least one open region, and at least one open region includes at least one irregular open region; and arranging a second mask on the first mask, where the second mask has at least one evaporation region, and a plurality of evaporation holes having the same shape are arranged in each evaporation region; where the at least one open region corresponds to the at least one evaporation region respectively, and the orthographic projection of each irregular open region on the second mask is located in a corresponding evaporation region.

Optionally, the second mask further has a buffer region surrounding each evaporation region; the plurality of sub-masks include at least one irregular sub-mask, each irregular sub-mask includes a strip structure and a protruding structure extending outward from an edge of the strip structure, an orthographic projection of the strip structure on the second mask is located in the buffer region, and an orthographic projection of the protruding structure on the second mask at least partially coincides with the evaporation region.

Optionally, the step of arranging a first mask on the frame includes: sequentially arranging a plurality of first sub-masks along a first direction on the frame; and sequentially arranging a plurality of second sub-masks along a second direction on the frame provided with the plurality of first sub-masks, where the plurality of first sub-masks and the plurality of second sub-masks form the at least one open region, and the first direction is perpendicular to the second direction; where at least one of the plurality of first sub-masks and the plurality of second sub-masks are the irregular sub-masks, and the at least one open region is an irregular open region.

Optionally, the protruding structure is arranged at a designated position on each irregular sub-mask, and the designated position is an edge close to the corresponding irregular open region at an intersection with the other sub-masks.

Optionally, the evaporation region has a rectangle shape, the buffer region has a rectangular ring shape, and the irregular open region has a rounded rectangle shape.

Optionally, the frame is a metal frame, the first mask is a metal shielding sheet mask, and the second mask is a fine metal mask; the step of arranging a first mask on the frame includes: welding the first mask onto the frame; and the step of arranging a second mask on the first mask includes: welding the second mask onto the first mask.

Optionally, the protruding structure is arranged at a designated position on each irregular sub-mask, and the designated position is an edge close to a corresponding irregular open region at an intersection with the other sub-masks.

### BRIEF DESCRIPTION OF THE DRAWINGS

FIG. 1 is a schematic diagram of a structure of a mask assembly known by the inventor(s);

FIG. 2 is a schematic diagram of a structure of a mask assembly provided in an embodiment of the present disclosure;

FIG. 3 is a schematic diagram of a structure of a second mask plate provided in an embodiment of the present disclosure;

FIG. 4 is a schematic diagram of a structure of a first mask plate provided in an embodiment of the present disclosure;

FIG. 5 is a schematic diagram of a structure of an irregular sub-mask provided in an embodiment of the present disclosure;

FIG. 6 is a schematic diagram of a structure of another irregular sub-mask provided in an embodiment of the present disclosure;

FIG. 7 is a schematic diagram of a structure of yet another irregular sub-mask provided in an embodiment of the present disclosure;

FIG. 8 is a schematic diagram of a structure of still yet another irregular sub-mask provided in an embodiment of the present disclosure; and

FIG. 9 is a flowchart of a method for manufacturing a mask assembly provided in an embodiment of the present disclosure.

### DETAILED DESCRIPTION

To make the principles and advantages of the present disclosure more clear, embodiments of the present disclosure are further described in detail below in combination with the accompanying drawings.

An OLED display includes a plurality of pixels arranged in a matrix. At present, an evaporation machine is generally used in coordination with a mask assembly, and an OLED material can be evaporated on a substrate by a manner of evaporation, so as to form an organic light-emitting pattern on the substrate to obtain an array substrate.

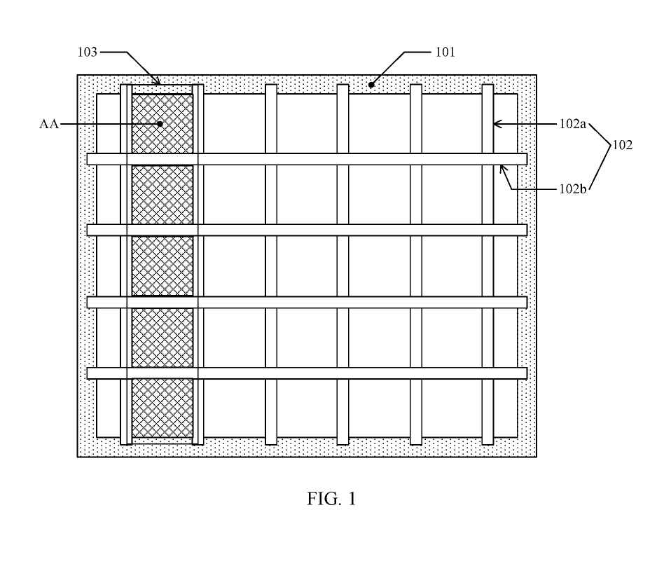

FIG. 1 illustrates a schematic diagram of a structure of a mask assembly known by the inventor(s). As shown in FIG. 1, the mask assembly includes: a metal frame 101, a metal shielding sheet mask 102 and an FMM 103. The metal shielding sheet mask 102 herein includes a first strip metal shielding sheet 102a array and a second strip metal shielding sheet 102b array that are perpendicular to each other. At present, the metal shielding sheet mask is generally welded on the metal frame, and the FMM is then welded on the metal shielding sheet mask, so as to maintain a stability of the structure of the mask assembly. The metal shielding sheet mask is used to shield the gap between adjacent FMMs during the evaporation and to support the FMM. An evaporation region of the mask assembly is an evaporation region of the FMM. As shown in FIG. 1, when the evaporation region AA of the FMM 103 is a rectangular region, a manufactured display panel can be a rectangular display panel. In order to realize an irregular display panel, an irregular evaporation region is generally designed on the FMM (for example, a rounded corner can be designed at the edge of the evaporation region). The irregular evaporation region is obtained by designing the evaporation holes on the edge of the evaporation region as irregular evaporation holes, so that the OLED material can pass through the evaporation holes in the irregular evaporation region and form an irregular display panel. Due to the irregular shape of the edge of the irregular evaporation region, the surface of the FMM tends to be uneven due to uneven stress release at the edge position when the FMM is welded onto the metal shielding sheet mask. When the mask assembly is used for evaporation, the surface of the FMM may be uneven, which may cause a phenomenon of poor color mixing on the display panel, and the manufactured display panel has low display reliability.

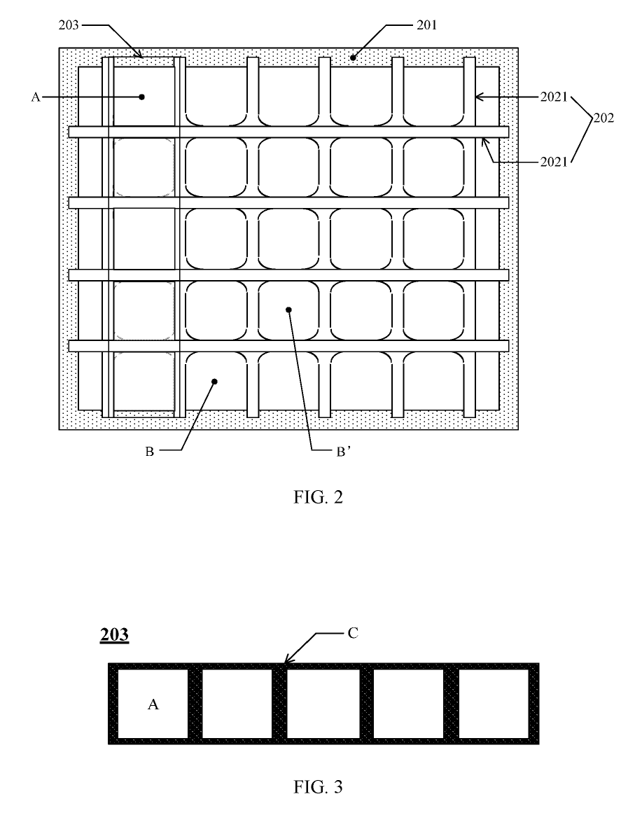

FIG. 2 illustrates a schematic diagram of a structure of a mask assembly provided in an embodiment of the present disclosure. As shown in FIG. 2, the mask assembly may include a frame 201, and a first mask 202 and a second mask 203 that are stacked on the frame 201.

Herein, the second mask 203 has at least one evaporation region A. and each evaporation region A is provided with a plurality of evaporation holes having the same shape (not shown in the drawings).

The first mask 202 includes a plurality of cross-arranged sub-masks 2021, the plurality of cross-arranged sub-masks 2021 define at least one open region B, the at least one open region B is in one-to-one correspondence to the at least one evaporation region A, the at least one open region B includes at least one irregular open region B′, and an orthographic projection of each irregular open region B′ on the second mask 203 is located in a corresponding evaporation region A.

Herein, a plurality of evaporation holes provided in the evaporation region are used to make the evaporation material pass in the evaporation process, so as to form a plurality of pixels on a substrate. The formed plurality of pixels correspond to a plurality of evaporation holes one by one.

Exemplarily, the mask assembly provided in the embodiments of the present disclosure is generally provided to form a display motherboard (also referred to as a display big-board). After being manufactured, the display mother board is cut to obtain a plurality of display panels. Herein, one evaporation region of a mask assembly can be manufactured as a display panel correspondingly. Since the orthographic projection of the irregular open region on the second mask is located in the corresponding evaporation region, when evaporation is performed through the evaporation region, part of the evaporation region is shielded by the first mask, and a shape of the manufactured display panel is the same as a shape of the irregular open region, that is, the manufactured display panel is an irregular display panel.

In summary, for the mask assembly provided in the embodiments of the present disclosure, since the first mask includes at least one irregular open region, the first mask and the second mask are stacked to make the orthographic projection of the irregular open region on the second mask located within the evaporation region of the second mask, so that the mask assembly can form an irregular evaporation region, without changing the shape of the evaporation region of the second mask. Therefore, when the second mask is arranged on the first mask, the flatness of the surface of the second mask can be ensured. When the mask assembly provided in the embodiments of the present disclosure is used to manufacture an irregular display panel, the phenomenon of poor color mixing during evaporation due to the uneven surface of the second mask can be avoided, and the display reliability of the manufactured display panel can be improved.

Optionally, as shown in FIG. 3, the second mask 203 has at least one evaporation region A and a buffer region C surrounding each evaporation region A.

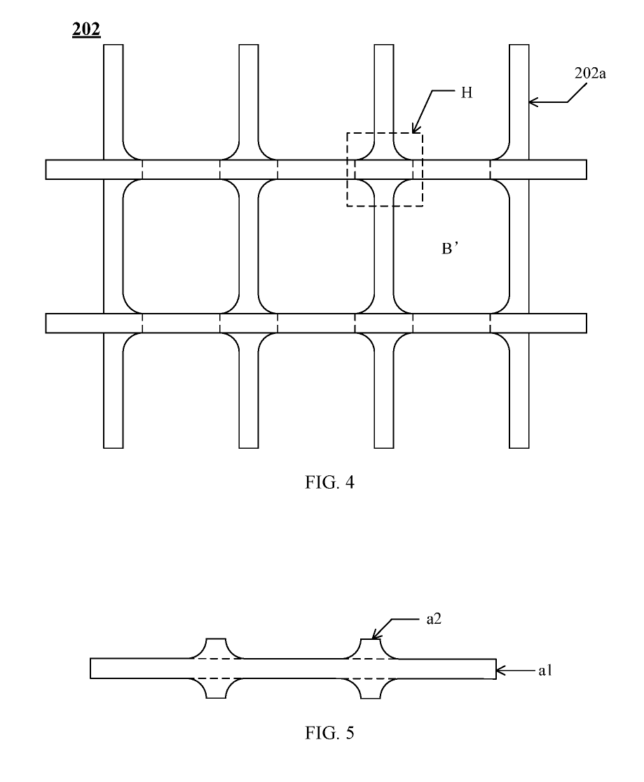

As shown in FIG. 4, the first mask 202 may include at least one irregular sub-mask 202a for defining at least one irregular open region B′. The sub-masks in the first mask, except for the irregular sub-masks therein, are ordinary masks with a shape of strip, that is, except for the irregular sub-masks, the sub-masks in the first mask have strip structures.

As shown in FIG. 5, each of the irregular sub-masks includes a strip structure a1, and a protruding structure a2 extending outward from an edge of the strip structure a1. The orthogonal projection of the strip structure a1 on the second mask is located within the buffer region, and the orthographic projection of the protruding structure a2 on the second mask at least partially coincides with the evaporation region.

Although uneven stress release may occur in the irregular sub-masks, on the one hand, in practical applications, the accuracy requirement for the second mask (e.g., 5 μm) is much higher than that for the irregular sub-masks (e.g., 100 μm). Slight deformation of the irregular sub-masks due to uneven stress release are acceptable in the production process; on the other hand, since a thickness of the irregular sub-masks (50-100 μm) is greater than a thickness of the second mask (25-35 μm), the deformation degree of the irregular sub-masks provided in the embodiments of the present disclosure is far less than the deformation degree of the second mask in the related art.

In the embodiments of the present disclosure, since the orthographic projection of the protruding structure on the second mask at least partially coincides with the evaporation region, when the mask assembly is adopted in the evaporation process, the protruding structure can shield the region coinciding with the evaporation region of the second mask, so as to form an irregular evaporation region of the mask assembly. There is no need to design an irregular evaporation region on the second mask, which improves the reliability of the evaporation process, and ensures the display performance of the manufactured display panel.

Optionally, at least one open region in the first mask may be an irregular open region. The first mask includes a plurality of first sub-masks arranged in an array along a first direction and a plurality of second sub-masks arranged in an array along a second direction, and the first direction is perpendicular to the second direction.

Exemplarily, the plurality of first sub-masks are all irregular sub-masks, and the plurality of second sub-masks are all strip sub-masks; or, the plurality of first sub-masks are all strip sub-masks, and the plurality of second sub-masks are all irregular sub-masks; or, the plurality of first sub-masks and the plurality of second sub-masks are all irregular sub-masks; or a part of the first sub-masks are strip sub-masks, the other part of the first sub-masks are irregular sub-masks, a part of the second sub-masks are strip sub-masks, and the other part of second sub-masks are irregular sub-masks, which are not limited in the embodiments of the present disclosure.

Optionally, a part of a plurality of open regions included in the first mask are irregular open regions, and the other part of open regions are normal open regions, that is, rectangular open regions; or, a plurality of open regions included in the first mask are irregular open regions, and the shapes of the plurality of irregular open regions are different. For example, a part of the irregular open regions are rounded rectangles, and the other part of the irregular open regions are round, so as to realize that the display panels having different shapes are manufactured by using same mask assemblies; or, the plurality of open regions included in the first mask are a plurality of irregular open regions having the same shape, which are not limited in the embodiments of the present disclosure.

In the embodiments of the present disclosure, the open region in the first mask may be defined by the first sub-mask and the second sub-mask. When at least one of the first sub-mask and the second sub-mask for defining a target open region is an irregular sub-mask, the target open region is an irregular open region. There is no limitation on whether the first sub-mask is an irregular sub-mask, or the second sub-mask is an irregular sub-mask in the embodiments of the present disclosure, as long as it is ensured that a protruding structure exists at the inner edge of the open region of the formed first mask.

Optionally, a protruding structure is provided at a designated position on each irregular sub-mask. Referring to FIG. 4, the designated position H may be an edge close to a corresponding irregular open region at the intersection with other sub-masks.

Exemplarily, the evaporation region may have a rectangular shape, the buffer region may have a rectangular ring shape, and the irregular open region may be a rounded rectangle. A rounded-corner display panel can be manufactured by adopting such a mask assembly.

Optionally, the structure of the irregular sub-mask for forming the irregular open region with a rounded rectangle shape may be various. The embodiments of the present disclosure make explanations by taking the following two structures as examples, and the detailed process is as follows:

As shown in FIG. 5, the first irregular sub-mask includes a strip structure a1 and a protruding structure a2. Each protruding structure a2 is a trapezoid with curved sides, and the trapezoid with curved edges includes two base sides parallel to each other and two curved sides connected to the two base sides respectively. The orthogonal projections of the two curved sides on the second mask are located in the evaporation region, and the orthogonal projections of two base sides on the second mask are located in the buffer region.

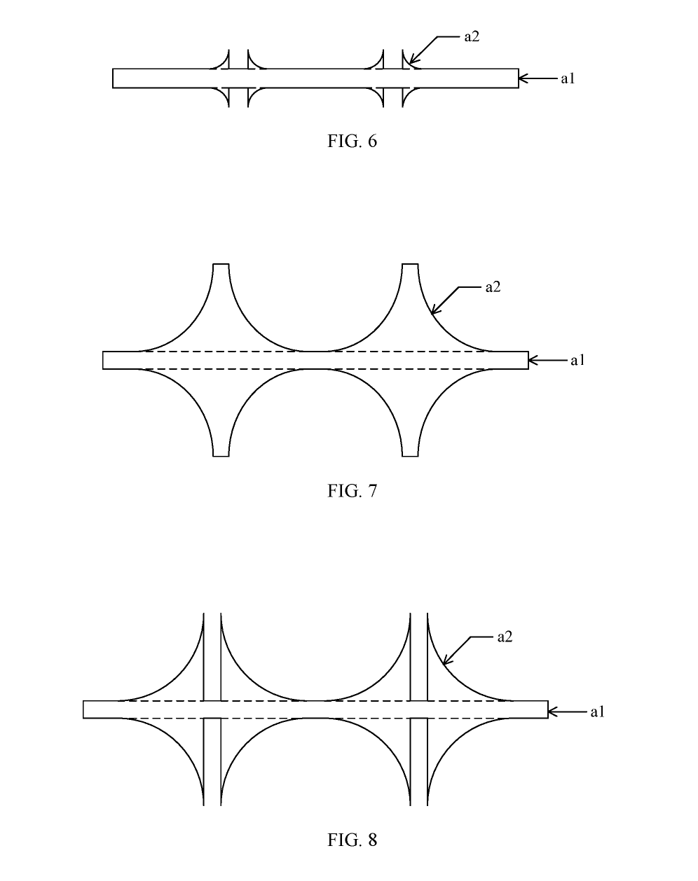

As shown in FIG. 6, the second irregular sub-mask includes a strip structure a1 and a protruding structure a2. Each protruding structure a2 is a triangle with curved sides, and the triangle with curved sides includes at least one curved side. An orthographic projection of a target curved side in the at least one curved side on the second mask is located in the evaporation region. Except for the target curved side, the orthographic projections of the other sides of the triangle with curved sides on the second mask are located in the buffer region.

Optionally, in the embodiments of the present disclosure, the irregular sub-masks in the first mask may include at least one of an irregular sub-mask shown in FIG. 5 and an irregular sub-mask shown in FIG. 6, as long as each open region formed after all the first sub-masks and all the second sub-masks are combined is a rounded-corner open region.

Optionally, the irregular open region formed in the first mask may also be a circular open region, and the irregular sub-mask includes a strip structure a1 and a protruding structure a2. The two protruding structures may be shown in FIG. 7 and FIG. 8 respectively. A circular display panel can be manufactured by using a first mask including a circular open region in combination with a second mask.

Of course, the irregular open region may also be an elliptical open region, a regular polygon open region, or the like, for manufacturing other irregular display panels. The corresponding irregular sub-mask may be a simple deformation of the above-mentioned irregular sub-mask, which is not repeated herein.

Optionally, the first mask may be a metal shielding sheet mask, and the second mask may be a fine metal mask.

Optionally, the frame may be a metal frame, the first mask may be welded on the metal frame, and the second mask may be welded on the first mask.

In summary, for the mask assembly provided in the embodiments of the present disclosure, since the first mask includes at least one irregular open region and the first mask and the second mask are stacked to make the orthographic projection of the irregular open region on the second mask located within the evaporation region of the second mask, so that the mask assembly can form an irregular evaporation region, without changing the shape of the evaporation region of the second mask. Therefore, when the second mask is arranged on the first mask, the flatness of the surface of the second mask can be ensured. When the mask assembly provided in the embodiment of the present disclosure is used to manufacture an irregular display panel, the phenomenon of poor color mixing during evaporation due to the uneven surface of the second mask can be avoided, and the display reliability of the manufactured display panel can be improved.

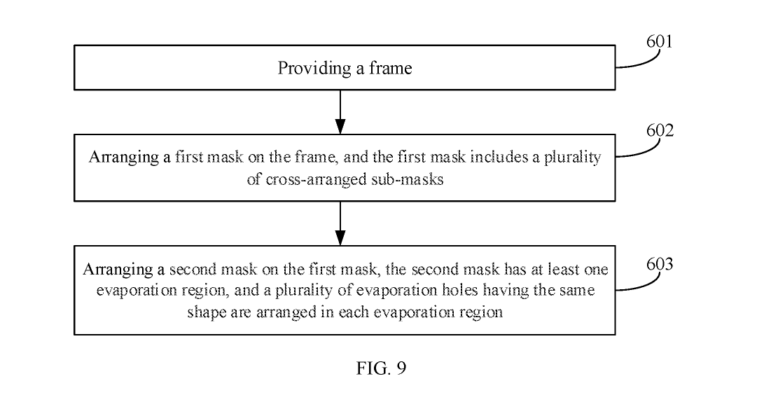

FIG. 9 shows a flowchart of a method for manufacturing a mask assembly provided in an embodiment of the present disclosure. As shown in FIG. 9, the method includes the following operation processes.

A frame is provided in step 601.

A first mask is arranged on the frame in step 602, and the first mask includes a plurality of cross-arranged sub-masks.

Herein, the plurality of cross-arranged sub-masks define at least one open region, and at least one open region includes at least one irregular open region.

A second mask is arranged on the first mask in step 603, the second mask has at least one evaporation region, and a plurality of evaporation holes having the same shape are arranged in each evaporation region.

Herein, the at least one open region is in one-to-one correspondence to the at least one evaporation region, and the orthographic projection of each irregular open region on the second mask is located in a corresponding evaporation region.

In summary, for the method for manufacturing a mask assembly provided in the embodiments of the present disclosure, since the first mask includes at least one irregular open region, and the first mask and the second mask are stacked to make the orthographic projection of the irregular open region on the second mask located in the evaporation region of the second mask, so that the mask assembly can form an irregular evaporation region, without changing the shape of the evaporation region of the second mask. Therefore, when the second mask is disposed on the first mask, the flatness of the surface of the second mask can be ensured. According to the method for manufacturing the mask assembly provided in the embodiments of the present disclosure, when the irregular display panel is manufactured, the phenomenon of poor color mixing during evaporation due to the uneven surface of the second mask can be avoided, and the display reliability of the manufactured display panel can be improved.

Optionally, as shown in FIG. 3, the second mask 203 has at least one evaporation region A and a buffer region C surrounding each evaporation region A. As shown in FIG. 4, the first mask 202 may include at least one irregular sub-mask 202a for defining at least one irregular open region B′. The sub-masks in the first mask, except for the irregular sub-masks therein, are ordinary masks with a shape of strip, that is, except for the irregular sub-masks, the sub-masks in the first mask have strip structures.

As shown in FIG. 5, each of the irregular sub-masks includes a strip structure a1 and a protruding structure a2 extending outward from an edge of the strip structure a1. The orthographic projection of the strip structure a1 on the second mask is located within the buffer region, and the orthographic projection of the protruding structure a2 on the second mask at least partially coincides with the evaporation region.

In the embodiments of the present disclosure, since the orthographic projection of the protruding structure on the second mask at least partially coincides with the evaporation region, when the mask assembly is adopted in the evaporation process, the protruding structure can shield the region coinciding with the evaporation region of the second mask, so as to form an irregular evaporation region of the mask assembly. There is no need to design an irregular evaporation region on the second mask, which improves the reliability of the evaporation process, and thus ensures the display performance of the manufactured display panel.

Optionally, the step of arranging the first mask plate on the frame may include the following steps.

A plurality of first sub-masks are sequentially arranged along a first direction on the frame in step S21.

A plurality of second sub-masks are sequentially arranged along a second direction on the frame provided with the plurality of first sub-masks, where the plurality of first sub-masks and the plurality of second sub-masks form at least one open region, and the first direction is perpendicular to the second direction.

Optionally, at least one of the plurality of first sub-masks and the plurality of second sub-masks is the irregular sub-mask, and at least one open region is an irregular open region.

Optionally, a part of the plurality of open regions included in the first mask are irregular open regions, and the other part of the open regions are normal open regions, that is, rectangular open regions; or, the plurality of open regions included in the first mask is all irregular open regions, and the shapes of the plurality of irregular open regions are different. For example, a part of the irregular open regions are rounded rectangles, and the other part of the irregular open regions are round; or, the plurality of open regions included in the first mask are a plurality of irregular open regions having the same shape, which is not limited in the embodiments of the present disclosure.

Optionally, a protruding structure is provided at a designated position on each irregular sub-mask defining each irregular open region. Referring to FIG. 4, the designated position H may be an edge close to a corresponding irregular open region at the intersection with other sub-masks.

Optionally, the evaporation region may have a rectangular shape, the buffer region may have a rectangular ring shape, and the irregular open region may have a rounded rectangle shape. A rounded-corner display panel can be manufactured by adopting such a mask assembly.

Optionally, the frame may be a metal frame, the first mask may be a metal shielding sheet mask, and the second mask may be a fine metal mask. Then the first mask may be welded onto the frame; and the second mask may be welded onto the first mask.

In summary, for the method for manufacturing a mask assembly provided in the embodiment of the present disclosure, since the first mask includes at least one irregular open region and the first mask and the second mask are stacked to make the orthographic projection of the irregular open region on the second mask is located in the evaporation region of the second mask, so that the mask assembly can form an irregular evaporation region, without changing the shape of the evaporation region of the second mask. Therefore, when the second mask is disposed on the first mask, the flatness of the surface of the second mask can be ensured. According to the method for manufacturing the mask assembly provided in the embodiments of the present disclosure, when the irregular display panel is manufactured, the phenomenon of poor color mixing during evaporation due to the uneven surface of the second mask can be avoided, and the display reliability of the manufactured display panel can be improved.

The structures of the mask assemblies involved in the above-mentioned method embodiments have been described in detail in the device embodiments, which are not repeated here.

The foregoing is merely optional embodiments of the present disclosure, and are not intended to limit the present disclosure. Any modifications, equivalent substitutions, improvements, and etc., within the spirit and principles of the disclosure, falls into the protection scope of the present disclosure.

What is claimed is:

1. A mask assembly, comprising:
a frame, and a first mask and a second mask stacked on the frame;
wherein the second mask has at least one evaporation region, and each evaporation region is provided with a plurality of evaporation holes having the same shape; and
the first mask includes a plurality of cross-arranged sub-masks, the plurality of cross-arranged sub-masks define at least one open region, the at least one open region is in one-to-one correspondence to the at least one evaporation region, the at least one open region includes at least one irregular open region, and an orthographic projection of each irregular open region on the second mask is located in a corresponding evaporation region.

2. The mask assembly according to claim 1, wherein the second mask further has a buffer region surrounding each evaporation region; and
the plurality of sub-masks include at least one irregular sub-mask, each irregular sub-mask includes a strip structure and a protruding structure extending outward from an edge of the strip structure, an orthographic projection of the strip structure on the second mask is located in the buffer region, and an orthographic projection of the protruding structure on the second mask at least partially coincides with the evaporation region.

3. The mask assembly according to claim 2, wherein the at least one open region is an irregular open region, the plurality of sub-masks comprise a plurality of first sub-masks arranged in a array along a first direction and a plurality of second sub-masks arranged in an array along a second direction, and the first direction is perpendicular to the second direction; and
the plurality of first sub-masks are the irregular sub-masks, and the plurality of second sub-masks are strip sub-masks.

4. The mask assembly according to claim 2, wherein the at least one open region is an irregular open region, the plurality of sub-masks comprise a plurality of first sub-masks arranged in an array along a first direction and a plurality of second sub-masks arranged in an array along a second direction, and the first direction is perpendicular to the second direction; and
the plurality of first sub-masks are strip sub-masks, and the plurality of second sub-masks are the irregular sub-masks.

5. The mask assembly according to claim 2, wherein the at least one open region is an irregular open region, the plurality of sub-masks comprise a plurality of first sub-masks arranged in an array along a first direction and a plurality of second sub-masks arranged in an array along a second direction, and the first direction is perpendicular to the second direction; and
the plurality of first sub-masks and the plurality of second sub-masks are all the irregular sub-masks.

6. The mask assembly according to claim 2, wherein the protruding structure is arranged at a designated position on each irregular sub-mask, and the designated position is an edge close to a corresponding irregular open region at an intersection with the other sub-masks.

7. The mask assembly according to claim 6, wherein the evaporation region has a rectangular shape, the buffer region has a rectangular ring shape, and the irregular open region has a rounded rectangle shape.

8. The mask assembly according to claim 7, wherein each protruding structure is a trapezoid with curved edges, the trapezoid with curved edges includes two base sides parallel to each other and two curved sides connected to the two base sides respectively, orthogonal projections of the two curved sides on the second mask are located in the evaporation region, and orthogonal projections of the two base sides on the second mask are located in the buffer region.

9. The mask assembly according to claim 7, wherein each protruding structure is a triangle with curved sides, the triangle with curved sides includes at least one curved side, an orthographic projection of a target curved side in the at least one curved side on the second mask is located in the evaporation region, and except for the target curved side, orthographic projections of the other sides of the triangle with curved sides on the second mask are located in the buffer region.

10. The mask assembly according to claim 1, wherein the first mask is a metal shielding sheet mask, and the second mask is a fine metal mask.

11. The mask assembly according to claim 10, wherein the frame is a metal frame, the first mask is welded on the metal frame, and the second mask is welded on the first mask.

12. The mask assembly according to claim 3, wherein the protruding structure is arranged at a designated position on each irregular sub-mask, and the designated position is an edge close to a corresponding irregular open region at an intersection with the other sub-masks.

13. A method for manufacturing a mask assembly, comprising steps of:
providing a frame;
arranging a first mask on the frame, wherein the first mask includes a plurality of cross-arranged sub-masks, the plurality of cross-arranged sub-masks define at least one open region, and at least one open region includes at least one irregular open region; and
arranging a second mask on the first mask, wherein the second mask has at least one evaporation region, and a plurality of evaporation holes having the same shape are arranged in each evaporation region;
wherein the at least one open region corresponds to the at least one evaporation region respectively, and the orthographic projection of each irregular open region on the second mask is located in a corresponding evaporation region.

14. The method according to claim 13, wherein the second mask further has a buffer region surrounding each evaporation region; and
the plurality of sub-masks include at least one irregular sub-mask, each irregular sub-mask includes a strip structure and a protruding structure extending outward from an edge of the strip structure, an orthographic projection of the strip structure on the second mask is located in the buffer region, and an orthographic projection of the protruding structure on the second mask at least partially coincides with the evaporation region.

15. The method according to claim 14, wherein the step of arranging a first mask on the frame comprises:
sequentially arranging a plurality of first sub-masks along a first direction on the frame; and
sequentially arranging a plurality of second sub-masks along a second direction on the frame provided with the plurality of first sub-masks, wherein the plurality of first sub-masks and the plurality of second sub-masks form the at least one open region, and the first direction is perpendicular to the second direction;
wherein at least one of the plurality of first sub-masks and the plurality of second sub-masks are the irregular sub-masks, and the at least one open region is an irregular open region.

16. The method according to claim 14, wherein the protruding structure is arranged at a designated position on each irregular sub-mask, and the designated position is an edge close to the corresponding irregular open region at an intersection with the other sub-masks.

17. The method according to claim 16, wherein the evaporation region has a rectangle shape, the buffer region has a rectangular ring shape, and the irregular open region has a rounded rectangle shape.

18. The method according to claim 13, wherein the frame is a metal frame, the first mask is a metal shielding sheet mask, and the second mask is a fine metal mask:
the step of arranging a first mask on the frame comprises: welding the first mask onto the frame; and
the step of arranging a second mask on the first mask comprises: welding the second mask onto the first mask.

19. The method according to claim 15, wherein the protruding structure is arranged at a designated position on each irregular sub-mask, and the designated position is an edge close to a corresponding irregular open region at an intersection with the other sub-masks.
